(19) United States
(12) Patent Application Publication
(10) Pub. No.: US 2026/0239723 A1
(43) Pub. Date: Aug. 13, 2026

(54) SUPERJUNCTION SILICON CARBIDE SEMICONDUCTOR DEVICE AND METHOD OF MANUFACTURING SUPERJUNCTION SILICON CARBIDE SEMICONDUCTOR DEVICE

(71) Applicants: FUJI ELECTRIC CO., LTD., Kawasaki-shi (JP); NATIONAL INSTITUTE OF ADVANCED INDUSTRIAL SCIENCE AND TECHNOLOGY, Tokyo (JP)

(72) Inventors: Takeshi TAWARA, Tsukuba-city (JP); Kensuke TAKENAKA, Tsukuba-city (JP); Shinsuke HARADA, Tsukuba-city (JP); Mitsuru SOMETANI, Tsukuba-city (JP)

(73) Assignees: FUJI ELECTRIC CO., LTD., Kawasaki-shi (JP); NATIONAL INSTITUTE OF ADVANCED INDUSTRIAL SCIENCE AND TECHNOLOGY, Tokyo (JP)

(21) Appl. No.: 19/633,805

(22) Filed: Mar. 30, 2026

Related U.S. Application Data
(63) Continuation of application No. PCT/JP2024/037282, filed on Oct. 18, 2024.

(30) Foreign Application Priority Data
Nov. 7, 2023 (JP) 2023-189896

(51) Int. Cl. H10D 84/00; H10D 8/00; H10D 8/01; H10D 30/01; H10D 30/66; H10D 62/10; H10D 62/60; H10D 62/832; H10D 62/834; H10D 84/01

(52) U.S. Cl. CPC H10D 84/143; H10D 8/045; H10D 8/411; H10D 30/0297; H10D 30/668; H10D 62/124; H10D 62/60; H10D 62/8325; H10D 62/834; H10D 84/0109; H10D 62/103

(57) ABSTRACT

A superjunction silicon carbide semiconductor device has: a silicon carbide semiconductor substrate; a first semiconductor layer of a first conductivity type; a parallel pn region in which first column regions of the first conductivity type and second column regions of a second conductivity type are disposed repeatedly alternating each other; a second semiconductor layer of the first conductivity type; first semiconductor regions of the first conductivity type, trenches, gate electrodes, first and second electrodes. Second semiconductor regions are doped with a dopant of the second conductivity type and provided in the first semiconductor layer, at bottom surfaces of and in contact with second column regions. At boundaries between the second semiconductor regions and the second column regions, a concentration of the dopant of the second conductivity type decreases to 1/10 or less of a maximum concentration of the dopant of the second conductivity type of the second semiconductor regions.

### CROSS REFERENCE TO RELATED APPLICATIONS

This is a continuation application of International Application PCT/JP2024/37282 filed on Oct. 18, 2024, which claims priority from a Japanese Patent Application No. 2023-189896 filed on Nov. 7, 2023, the contents of which are incorporated herein by reference.

### BACKGROUND OF THE INVENTION

### 1. Field of the Invention

Embodiments of the disclosure relate to superjunction silicon carbide semiconductor device and a method of manufacturing a superjunction silicon carbide semiconductor device.

### 2. Description of the Related Art

Japanese Laid-Open Patent Publication No. 2011-176157 describes a technique of embedding a reverse conductive semiconductor layer in a trench and thereby forming a superjunction structure in a metal-oxide-semiconductor field effect transistor (MOSFET) semiconductor device having a silicon semiconductor. More specifically, a technique is described by which a relatively shallow trench is formed in a single conductive semiconductor layer, a reverse conductive dopant region is formed at a bottom of the trench, and the reverse conductive semiconductor layer is embedded in the trench, thereby forming substrate of a superjunction structure and a device region having at least one pn junction at a surface of the substrate. Japanese Laid-Open Patent Publication No. 2010-045245 also describes a similar technique.

International Publication No. WO 2020/110514 describes a technique of forming a superjunction structure in a MOSFET semiconductor device of silicon carbide semiconductor by a multi-epitaxy-implantation method that includes repeatedly forming a relatively thin epitaxial growth layer and selectively ion-implanting a dopant so that in the layer, the conductivity is reversed.

Japanese Laid-Open Patent Publication No. 2018-019053 describes a technique of forming a superjunction structure in a MOSFET semiconductor device of silicon carbide semiconductor, by a trench backfilling method that includes forming a deep trench in a relatively thick epitaxial growth layer and embedding a reverse conductive semiconductor layer in the trench.

### SUMMARY OF THE INVENTION

According to an embodiment of the present disclosure, a superjunction silicon carbide semiconductor device includes: a silicon carbide semiconductor substrate of a first conductivity type, having a front surface and a back surface; a first semiconductor layer of the first conductivity type, provided at the front surface of the silicon carbide semiconductor substrate, the first semiconductor layer having a first surface and a second surface opposite to each other, the second surface facing the silicon carbide semiconductor substrate; a parallel pn region in which a plurality of first column regions of the first conductivity type and a plurality of second column regions of a second conductivity type are disposed repeatedly alternating with each other in a plane parallel to the front surface of the silicon carbide semiconductor substrate, the parallel pn region being provided at the first surface of the first semiconductor layer, the parallel pn region having a first surface and a second surface opposite to each other, the second surface of the parallel pn region facing the silicon carbide semiconductor substrate; a second semiconductor layer of the second conductivity type, provided at the first surface of the parallel pn region; a plurality of first semiconductor regions of the first conductivity type, selectively provided in the second semiconductor layer and having a dopant concentration higher than that of the first semiconductor layer; a plurality of gate electrodes, each provided via one of a plurality of gate insulating films in contact with a portion of the second semiconductor layer and a portion of the plurality of first semiconductor regions; a first electrode in contact with the plurality of first semiconductor regions and the second semiconductor layer; a second electrode provided at the back surface of the silicon carbide semiconductor substrate; and a plurality of second semiconductor regions of the second conductivity type, doped with a dopant of the second conductivity type, provided in the first semiconductor layer, at bottom surfaces of the plurality of second column regions, and being in contact with the plurality of second column regions, respectively. A boundaries between the plurality of second semiconductor regions and the plurality of second column regions, a concentration of the dopant of the second conductivity type exhibits a concentration spike where the concentration decreases to 1/10 or less of a maximum concentration of the dopant of the second conductivity type of the plurality of second semiconductor regions.

Objects, features, and advantages of the present invention are specifically set forth in or will become apparent from the following detailed description of the invention when read in conjunction with the accompanying drawings.

### BRIEF DESCRIPTION OF THE DRAWINGS

FIG. 1 is a cross-section view depicting a structure of a SJ-MOSFET according to an embodiment.

FIG. 2 is a cross-sectional view schematically depicting a state of the superjunction silicon carbide semiconductor device according to the embodiment during manufacture.

FIG. 3 is a cross-sectional view schematically depicting a state of the superjunction silicon carbide semiconductor device according to the embodiment during manufacture.

FIG. 4 is a cross-sectional view schematically depicting a state of the superjunction silicon carbide semiconductor device according to the embodiment during manufacture.

FIG. 5 is a cross-sectional view schematically depicting a state of the superjunction silicon carbide semiconductor device according to the embodiment during manufacture.

FIG. 6 is a cross-sectional view schematically depicting a state of the superjunction silicon carbide semiconductor device according to the embodiment during manufacture.

FIG. 7 is a cross-sectional view schematically depicting a state of the superjunction silicon carbide semiconductor device according to the embodiment during manufacture.

FIG. 8 is a cross-sectional view schematically depicting a state of the superjunction silicon carbide semiconductor device according to the embodiment during manufacture.

FIG. 9 is a graph depicting calculated values of an Al concentration profile of p-type regions of the SJ-MOSFET according to the embodiment.

FIG. 10 is a graph depicting calculated values of Al and P concentration profiles of p-type regions of the SJ-MOSFET according to the embodiment.

FIG. 11 is a graph depicting calculated values of Al and Ar concentration profiles of p-type regions of the SJ-MOSFET according to the embodiment.

FIG. 12 depicts experimental results indicating fluctuation of on-voltage of a conventional SJ-MOSFET.

FIG. 13 is a plan view schematically depicting growth of stacking faults of the conventional SJ-MOSFET.

### DETAILED DESCRIPTION OF THE INVENTION

First, an outline of an embodiment of the present disclosure is described. (1) A superjunction silicon carbide semiconductor device according to one aspect of the present disclosure is as follows. At a front surface of a silicon carbide semiconductor substrate of a first conductivity type, a first semiconductor layer of the first conductivity type is provided. At a first surface of the first semiconductor layer, opposite to a second surface thereof facing the silicon carbide semiconductor substrate, a parallel pn region is provided in which first column regions of the first conductivity type and second column regions of a second conductivity type are disposed repeatedly alternating each other in a plane parallel to the front surface. At a first surface of the parallel pn region, opposite to a second surface thereof facing the silicon carbide semiconductor substrate, a second semiconductor layer of the second conductivity type is provided. In the second semiconductor layer, first semiconductor regions of the first conductivity type are selectively provided and have a dopant concentration higher than that of the first semiconductor layer. A gate electrode is provided via a gate insulating film in contact with a portion of the second semiconductor layer and portions of the first semiconductor regions. A first electrode in contact with the first semiconductor regions and the second semiconductor layer is provided. A second electrode is provided at a back surface of the silicon carbide semiconductor substrate. Second semiconductor regions of the second conductivity type and doped with a dopant of the second conductivity type are provided in the first semiconductor layer, at bottoms of the second column regions, the second semiconductor regions being in contact with the second column regions. At boundaries between the second semiconductor regions and the second column regions, a concentration of the dopant of the second conductivity type exhibits a concentration spike where the concentration decreases to 1/10 or less of a maximum concentration of the dopant of the second conductivity type of the second semiconductor regions.

According to the description above, after formation of SJ trenches, ion-implantation of a p-type dopant, etc. is performed at bottoms of the SJ trenches, thereby introducing in a drift layer (first semiconductor layer of the first conductivity type), defects due to the ion implantation. The defects expand during epitaxial growth of a p-type epitaxial layer (third semiconductor layer of the second conductivity type) and spread to the drift layer, whereby the lifetime of the drift layer may be reduced. Thus, during body diode conduction, degradation due to conduction may be suppressed.
(2) Further, in (1) above, each of the second semiconductor regions may be a region in the first semiconductor layer, implanted with the dopant of the second conductivity type, or the dopant of the second conductivity type and a dopant of the first conductivity type, or the dopant of the second conductivity type and a rare gas element.
(3) Further, in (2) above, the dopant of the second conductivity type is aluminum or boron; the dopant of the first conductivity type is phosphorus or nitrogen; and the rare gas element may be neon, argon, krypton, or xenon.
(4) Further, in any one of (1) to (3) above, the second semiconductor regions have a compensation concentration in a range of 1×10¹⁶/cm³ to 1×10¹⁷/cm³, and a maximum concentration of a sum of an implanted element may be not more than 2×10¹⁷/cm³.
(5) Further, in any one of (1) to (4) above, a thickness of each of the second semiconductor regions may be in a range of 0.1 μm to 1 μm.
(6) Further, in (1) above, the gate electrodes provided via the gate insulating film may be provided in trenches that penetrate through the first semiconductor regions and the second semiconductor layer and reach the first semiconductor layer.

According to the description above, the ion-implanted p-type regions are prevented from disappearing due to hydrogen etching when the p-type epitaxial layer is grown by epitaxy, enabling the defects to be introduced.
(7) A method of manufacturing a superjunction silicon carbide semiconductor device according to one aspect of the present disclosure is as follows. First, as a first process, a first semiconductor layer of a first conductivity type is formed at a front surface of a silicon carbide semiconductor substrate of the first conductivity type. Next, as a second process, SJ trenches are formed from a first surface of the first semiconductor layer, opposite to a second surface thereof facing the silicon carbide semiconductor substrate, the SJ trenches not reaching the silicon carbide semiconductor substrate. Next, as a third process, a dopant is ion-implanted at bottoms of the SJ trenches, thereby forming second semiconductor regions of a second conductivity type. Next, as a fourth process, a third semiconductor layer of the second conductivity type is grown by epitaxy so as to be embedded in the SJ trenches. Next, as a fifth process, a surface of the third semiconductor layer is ground, leaving the third semiconductor layer in the SJ trenches, thereby forming at the first surface of the first semiconductor layer, a parallel pn region in which first column regions of the first conductivity type and second column regions of the second conductivity type repeatedly alternate each other in a plane parallel to the front surface. Next, as a sixth process, a second semiconductor layer of the second conductivity type is formed at a first surface of the parallel pn region, opposite to a second surface thereof facing the silicon carbide semiconductor substrate. Next, as a seventh process, first semiconductor regions of the first conductivity type are selectively formed in the second semiconductor layer, the first semiconductor regions having a dopant concentration higher than that of the first semiconductor layer. Next, as an eighth process, a gate electrode is formed via a gate insulating film in contact with a portion of the second semiconductor layer and portions of the first semiconductor regions. Next, as a ninth process, a first electrode in contact with the plurality of first semiconductor regions and the second semiconductor layer is formed. Next, as a tenth process, a second electrode is formed at the back surface of the silicon carbide semiconductor substrate.
(8) Further, in (7) above, the dopant may be a dopant of the second conductivity type, or a dopant of the second conductivity type and a dopant of the first conductivity type, or a dopant of the second conductivity type and a rare gas element.
(9) Further, in (7) above, the eighth process may include forming trenches that penetrate through the first semiconductor regions and the second semiconductor layer and reach the first semiconductor layer, and the gate electrode being formed in the trenches via the gate insulating film.

Next, findings underlying the present disclosure are discussed. First, problems associated with a conventional superjunction silicon carbide semiconductor device are discussed. In a normal n-type channel vertical MOSFET, among multiple semiconductor layers formed in a semiconductor substrate, an n-type conductive layer (drift layer) is the semiconductor layer having the highest resistance. Electrical resistance of the n-type drift layer significantly affects the on-resistance of the entire vertical MOSFET. Reduction of the on-resistance of the entire vertical MOSFET may be realized by reducing a thickness of the n-type drift layer and shortening the current path.

However, in a vertical MOSFET, during an off-state, a depletion layer spreads to the high-resistance n-type drift layer and thereby has a function of sustaining the breakdown voltage. Thus, when the thickness of the n-type drift layer is decreased to reduce the on-resistance, the spreading of the depletion layer during the off-state is shortened, whereby the breakdown field strength is easily reached by a low applied voltage and the breakdown voltage decreases. On the other hand, to increase the breakdown voltage of the vertical MOSFET, the thickness of the n-type drift layer has to be increased and thus, the on-resistance increases. The described relationship between the on-resistance and the breakdown voltage is called a trade-off relationship and it is difficult to improve both in such a relationship. The trade-off relationship between the on-resistance and the breakdown voltage is known to similarly exist in semiconductor devices such as insulated gate bipolar transistors (IGBTs), bipolar transistors, and diodes.

As a structure of a semiconductor device to solve the problems described above, superjunction (SJ) structures are known (refer to International Publication No. WO 2020/110514 and Japanese Laid-Open Patent Publication No. 2018-019053).

A MOSFET having a superjunction structure (hereinafter, SJ-MOSFET) is formed using a wafer in which an n-type buffer layer and an n-type drift layer are grown on an n⁺-type the silicon carbide semiconductor substrate that has a high dopant concentration. P-type column regions that penetrate the n-type drift layer from a surface of the wafer without reaching the n⁺-type silicon carbide semiconductor substrate are provided. The p-type column regions may or may not reach the n⁺-type the silicon carbide semiconductor substrate.

Further, the n-type drift layer has a parallel structure (hereinafter referred to as a parallel pn structure) that forms an SJ structure in which p-type regions (p-type column regions) and n-type regions (portions of the n-type drift layer sandwiched between the p-type column regions, hereinafter referred to as n-type column regions) that extend in a direction orthogonal to the substrate main surface and have narrow widths in a plane parallel to the substrate main surface are alternately arranged in a plane parallel to the substrate main surface. The parallel pn structure may be referred to as a parallel pn region. The p-type column regions and the n-type column regions configuring the parallel pn structure are regions having increased dopant concentrations with respect to the n-type drift layer. In the parallel pn structure, a dopant amount, which is a product of dopant concentrations and areas of the p-type column regions and the n-type column regions, is substantially equivalent to a balance of charge, whereby in the off-state, a depletion layer spreads, the breakdown voltage is sustained, and both the breakdown voltage and a low on-resistance due to the dopant concentration may be achieved.

Among methods of manufacturing a superjunction silicon carbide semiconductor device, while a multi-epitaxy-implantation method forms the SJ structure by combining epitaxial growth and ion implantation (refer to International Publication No. WO 2020/110514), the formation of a deep SJ structure for high-voltage devices incurs higher costs. This is because deep ion implantation is difficult in silicon carbide semiconductors, and the thermal diffusion of dopants is also slight, so there are greater constraints on the thickness of the epitaxial growth layer per process compared to silicon semiconductors. Thus, a method has been proposed to form the SJ structure by forming a deep trench in a relatively thick n-type drift layer and filling the trench with a p-type epitaxial layer (trench backfilling method) (refer to Japanese Laid-Open Patent Publication No. 2018-019053).

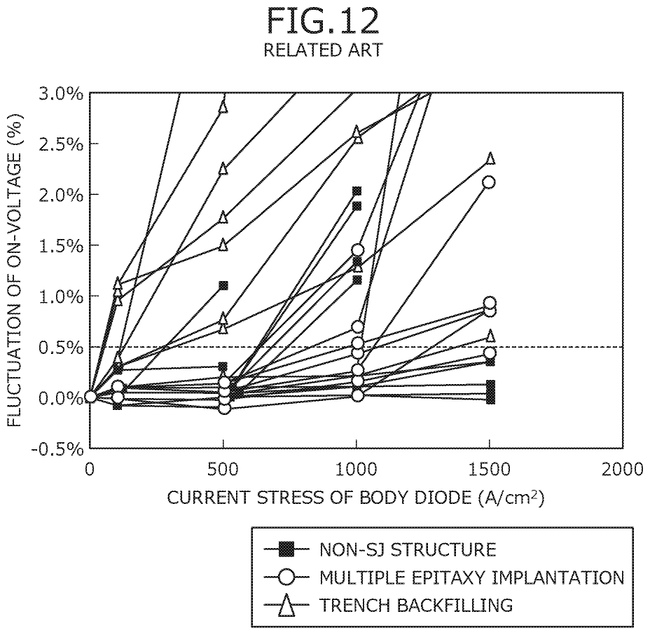

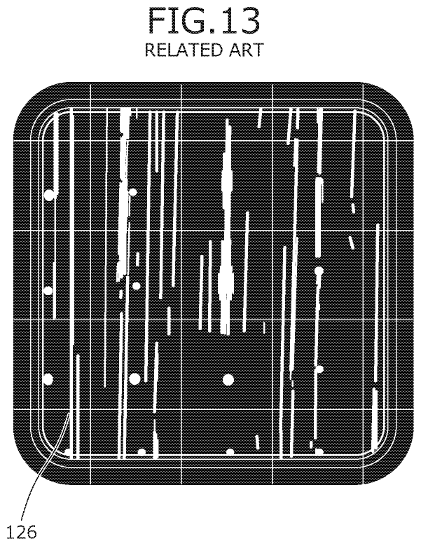

FIG. 12 depicts experimental results indicating fluctuation of the on-voltage of a conventional SJ-MOSFET. Three conventional structures including a non-SJ structure and those formed by, respectively, multi-epitaxy-implantation and trench backfilling are compared. In FIG. 12, a horizontal axis indicates body diode current stress in units of A/cm². A vertical axis indicates variation from an initial value of the on-voltage in units of %. In the figure, for the same structure (for example, the non-SJ structure), multiple measurement points (for example, black squares) having the same current stress value (for example, 500 A/cm²) are results when measurement locations were changed in a single sample. FIG. 13 is a device plan view depicting growth of stacking faults of the conventional SJ-MOSFET formed by the trench backfilling method and depicts experimental results when, in the device, the on-voltage varies, a surface electrode peels, and photoluminescence (PL) mapping measurement is performed with respect to stacking faults by an emission wavelength (420 nm).

In the trench backfilling method, during fabrication of the SJ structure, defects due to ion implantation are not introduced into the n-type drift layer like in the multi-epitaxy-implantation method. Thus, when the body diode of the SJ-MOSFET conducts, a large amount of carriers is injected, whereby the body diode is prone to degradation due to conduction. Thus, as depicted in FIG. 13, the present inventors discovered that in an instance of formation by the trench backfilling method, stacking faults 126 expand when current is applied and as depicted in FIG. 12, there is a problem in that fluctuation of the on-voltage becomes large even with low current stress. Conduction-related degradation due to the stacking faults is a phenomenon specific to silicon carbide semiconductors. For example, in FIG. 12, from the data for the current stress of 500 A/cm², it is found that the on-voltage variation is greater for trench backfilling (Δ) than for multi-epitaxy-implantation (◯). Furthermore, during body diode conduction, a large amount of carriers is injected and thus, there are problems with increased reverse recovery loss and turn-on loss during switching.

Embodiments of a superjunction silicon carbide semiconductor device and a method of manufacturing a superjunction silicon carbide semiconductor device according to the present invention will be described in detail with reference to the accompanying drawings. In the present description and accompanying drawings, layers and regions prefixed with n or p mean that majority carriers are electrons or holes. Additionally, + or − appended to n or p means that the impurity concentration is higher or lower, respectively, than layers and regions without + or −. Cases where symbols such as n's and p's that include + or − are the same indicate that concentrations are close and therefore, the concentrations are not necessarily equal. In the description of the embodiments below and the accompanying drawings, main portions that are identical will be given the same reference numerals and will not be repeatedly described. Further, with consideration of variation in manufacturing, description indicating the same or equal may be within 5%.

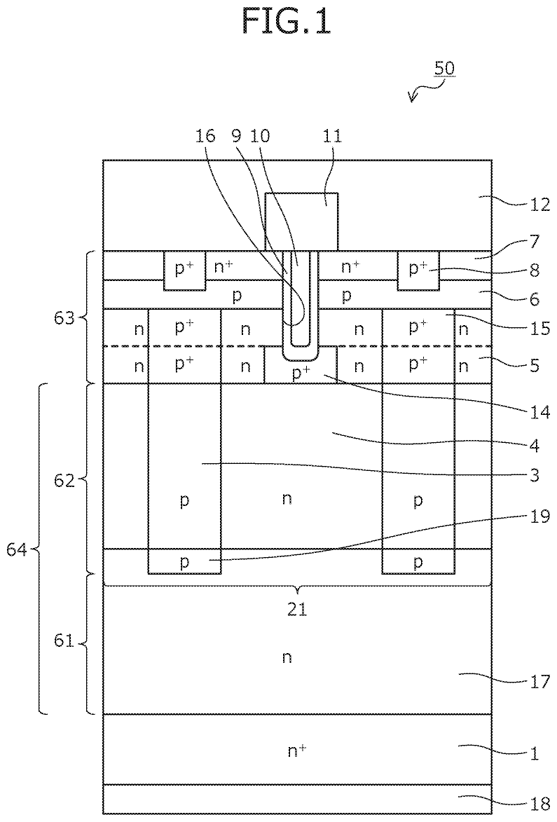

A superjunction semiconductor device according to the embodiment is described. FIG. 1 is a cross-section view depicting a structure of a SJ-MOSFET according to the embodiment. A superjunction silicon carbide semiconductor device according to the present disclosure is described taking a SJ-MOSFET 50 as an example. In the SJ-MOSFET 50 depicted in FIG. 1, a semiconductor chip (silicon carbide chip) contains silicon carbide and at a front surface thereof (surface having a later-described p-type base layer 6), metal oxide semiconductor (MOS) gates are provided. In FIG. 1, only one unit cell (functional unit of a device) is depicted and other unit cells adjacent thereto are not depicted.

As depicted in FIG. 1, in the SJ-MOSFET 50 according to the embodiment, a drift layer 64 is provided at a first main surface (front surface), for example, a (0001) plane (Si-surface), of an n⁺-type silicon carbide substrate (silicon carbide semiconductor substrate of a first conductivity type) 1. The n⁺-type silicon carbide substrate 1 is a silicon carbide single crystal substrate doped with, for example, nitrogen (N). The drift layer 64 includes an n-type buffer layer (first semiconductor layer of the first conductivity type) 17 constituting a bulk drift layer 61 and a SJ structure 62 provided at a front surface of the n-type buffer layer 17. The SJ structure 62 includes p-type column regions 3 and n-type column regions 4.

In the n-type column regions 4, at a first surface thereof opposite to a second surface thereof facing the n⁺-type silicon carbide substrate 1, n-type high-concentration regions 5 are selectively provided. The n-type high-concentration regions 5 constitute a high-concentration n-type drift layer having a dopant concentration that is lower than a dopant concentration of the n⁺-type silicon carbide substrate 1 and higher than a dopant concentration of the n-type column regions 4. The n-type high-concentration regions 5 constitute a so-called current spreading layer (CSL) that reduces carrier spreading resistance.

At a first surface of the drift layer 64, opposite to a second surface thereof facing the n⁺-type silicon carbide substrate 1, the p-type base layer (second semiconductor layer of a second conductivity type) 6 is provided. Hereinafter, the n⁺-type silicon carbide substrate 1, the bulk drift layer 61, the SJ structure 62, the n-type high-concentration regions 5, and the p-type base layer 6 combined are regarded as the silicon carbide semiconductor chip. The n-type buffer layer 17 constitutes the bulk drift layer 61, which has a thickness of about 4.4 μm and a dopant concentration of about 1.8×10¹⁶/cm³.

In the drift layer 64 of the SJ-MOSFET 50, a parallel pn structure 21 constituting the SJ structure 62 is provided. In the parallel pn structure 21, the n-type column regions (first columns of the first conductivity type) 4 and the p-type column regions (second columns of the second conductivity type) 3 are disposed repeatedly alternating with each other in a plane that is parallel to the front surface of the n⁺-type silicon carbide substrate 1. The n-type column regions 4 are provided so as to reach the n-type high-concentration regions 5 from the surface of the n-type buffer layer 17. The p-type column regions 3 have a dopant concentration of about 6×10¹⁶/cm³ and the n-type column regions 4 have a dopant concentration of about 3×10¹⁶/cm³. In FIG. 1, a solid line (boundary line) between the n-type buffer layer 17 and the n-type column regions 4 means that the n-type dopant concentration of the n-type column regions 4 is higher than that of the n-type buffer layer 17. The n-type buffer layer 17 and the n-type column regions 4 may be formed by epitaxial growth layers doped with the same concentration of an n-type dopant. In this instance, the boundary line between the n-type buffer layer 17 and the n-type column regions 4 is unnecessary.

In the embodiment, at bottom surfaces of the p-type column regions 3, p-type regions (second semiconductor regions of the second conductivity type) 19 are provided in the n-type buffer layer 17 so as to be in contact with the p-type column regions 3. While not depicted in detail, in the embodiment, when the SJ structure 62 is formed, after SJ trenches 24 (refer to FIG. 4) are formed, an ion implantation of, for example, Al is performed at bottoms of the SJ trenches 24, whereby the p-type regions 19 are formed. The p-type regions 19 are a p-type because Al is implanted into the n-type buffer layer 17 which contains N, and the dopant concentration of Al is higher than the dopant concentration of N.

The p-type regions 19 introduce into the drift layer 64, defects (crystal defects, ion implantation damage) formed by ion implantation. During formation of the SJ structure 62, the crystal defects diffuse during the epitaxial growth when a subsequent p-type epitaxial layer 22 (refer to FIG. 6) is formed, and spread to at least portions of the drift layer 64 around the p-type regions 19, whereby the lifetime of the drift layer 64 may be reduced. In particular, reduction of the lifetime of the n-type column regions 4 and the n-type buffer layer 17 adjacent to the p-type regions 19 is important. As a result, during body diode conduction, degradation due to the conduction may be suppressed. Furthermore, ion implanted regions are the p-type regions 19, which enable the depth of the SJ trenches 24 to be reduced by an amount equivalent thereto, whereby the etching time for the SJ trenches 24 and the time for embedding the p-type epitaxial layer 22 in the SJ trenches 24 may be shortened. As a result, reduced process costs may be expected. In the silicon carbide semiconductor, a phenomenon is observed in which after an impurity constituting a dopant is ion implanted and a heat treatment is performed, the impurity itself does not diffuse much, however, crystal defects (lattice defects) formed by the ion implantation expand due to the heat treatment. In FIG. 1, defects due to the ion implantation and distribution thereof after expansion are not depicted.

Further, as for the charge balance of the parallel pn structure 21, a product (the dopant amount) of the width of each of the p-type column regions 3 and the dopant concentration of the p-type column regions 3 is substantially equal to a product of (the dopant amount) the width of each the n-type column regions 4 and the dopant concentration of the n-type column regions 4 and is within ±5%. Thus, the parallel pn structure 21 is known as a structure that may obtain both low on-resistance and high-voltage characteristics concurrently.

As depicted in FIG. 1, at a second main surface (back surface, i.e., back surface of the silicon carbide semiconductor chip) of the n⁺-type silicon carbide substrate 1, a drain electrode (second electrode) 18 is provided. At a surface of the drain electrode 18, a drain electrode pad (not depicted) is provided.

In the silicon carbide semiconductor chip, at the first main surface thereof (on the side of p-type base layer 6), a trench structure is formed. The SJ-MOSFET 50 has a MOS structure 63 configured by the n-type high-concentration regions 5, the p-type base layer 6, n⁺-type source regions 7, p⁺-type contact regions 8, a gate insulating film 9, gate electrodes 10, and trenches 16. In particular, the trenches 16 penetrate through the p-type base layer 6 from a first surface of the p-type base layer 6 (the first surface facing the first main surface of silicon carbide semiconductor chip), opposite to a second surface thereof facing the n⁺-type silicon carbide substrate 1, and reach the n-type high-concentration regions 5. The gate insulating film 9 is formed along inner walls of the trenches 16, at the bottoms and sidewalls of the trenches 16; and the gate electrodes 10 are formed on the gate insulating film 9 in the trenches 16. The gate insulating film 9 insulates the gate electrodes 10 from the n-type high-concentration regions 5 and the p-type base layer 6. A portion of each of the gate electrodes 10 may protrude from a top of each of the trenches 16 in a direction toward a later-described source electrode 12.

In the n-type high-concentration regions 5, first p⁺-type base regions 14 and second p⁺-type base regions 15 are each selectively provided. Among the bottom and bottom corner portions of the trenches 16, the first p⁺-type base regions 14 cover at least the bottoms of the trenches 16. The bottom corner portions of the trenches 16 are boundaries between the bottom and sidewalls of the trenches 16. The second p⁺-type base regions 15 are provided between the trenches 16, to a same depth from the surface of the n-type high-concentration regions 5 facing the p-type base layer 6, as that of the first p⁺-type base regions 14.

Pn junctions between the first p⁺-type base regions 14, the second p⁺-type base regions 15, and the n-type column regions 4 are formed at deep positions closer to the drain electrode than are the bottoms of the trenches 16. Depth positions of the ends of the first p⁺-type base regions 14 and the second p⁺-type base regions 15 facing the drain electrode may be variously changed according to design specifications provided that the pn junctions between the first p⁺-type base regions 14, the second p⁺-type base regions 15, and the n-type column regions 4 are at deep positions closer to the drain electrode than are the bottoms of the trenches 16. The first p⁺-type base regions 14 and the second p⁺-type base regions 15 may prevent application of high electric field to portions of the gate insulating film 9 along the bottoms of the trenches 16.

In the p-type base layer 6, at the surface thereof facing the first main surface of the wafer, the n⁺-type source regions (first semiconductor regions of the first conductivity type) 7 are selectively provided. Further, the p⁺-type contact regions 8 may be provided. The n⁺-type source regions 7 are in contact with the trenches 16. Further, the n⁺-type source regions 7 and the p⁺-type contact regions 8 are in contact with each other. In the present description, the front surface refers to the first main surface, for example, a (0001) plane (Si-face) of the n⁺-type silicon carbide substrate 1; “above the surface of a semiconductor layer” refers to a semiconductor region/semiconductor layer being provided above the surface of the semiconductor layer; and “provided in a semiconductor layer” refers to a semiconductor region/semiconductor layer that is provided in a semiconductor layer and exposed at the surface of the semiconductor layer.

An interlayer insulating film 11 is provided in an entire area of the first main surface of the silicon carbide semiconductor chip so as to cover the gate electrodes 10 embedded in the trenches 16. The source electrode 12 is in contact with the n⁺-type source regions 7 and the p-type base layer 6 via contact holes opened in the interlayer insulating film 11. In an instance in which the p⁺-type contact regions 8 are provided, the source electrode 12 is in contact with the n⁺-type source regions 7 and the p⁺-type contact regions 8. The source electrode 12 is formed by, for example, a NiSi film. The source electrode 12 is electrically insulated from the gate electrodes 10 by the interlayer insulating film 11. Above the source electrode 12, a source electrode pad (not depicted) containing Al or AlSi is provided. Between the source electrode 12 and the interlayer insulating film 11, for example, a barrier metal (not depicted) containing Ti and TiN and preventing diffusion of metal atoms from the source electrode 12 to the gate electrodes 10 may be provided.

In FIG. 1, the body diode of the SJ-MOSFET that is problematic is a parasitic pn diode between the p-type base layer 6 and each of the n-type high-concentration regions 5. The p-type base layer 6 is connected to the source electrode 12 via the p⁺-type contact regions 8. The n-type high-concentration regions 5 are connected to the drain electrode 18 via the n-type column regions 4, the n-type buffer layer 17, and the n⁺-type silicon carbide substrate 1. When the SJ-MOSFET is in a reflux mode, the potential of the source electrode 12 becomes higher than the potential of the drain electrode 18 and when the threshold voltage of the body diodes is exceeded, the body diodes conduct and carriers are injected. A portion of the current paths of the body diodes overlaps the source-drain current path of the SJ-MOSFET and thus, as described above, degradation due to conduction of the body diodes leads to degradation of characteristics of the SJ-MOSFET.

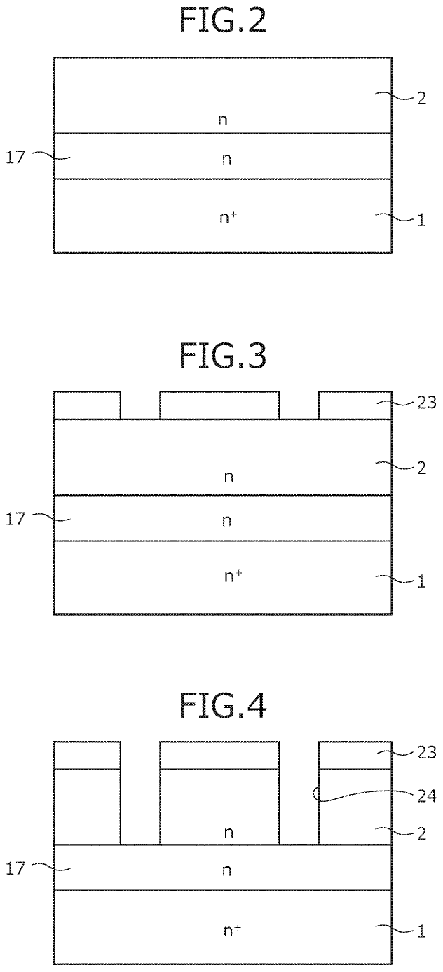

Next, a method of manufacturing the superjunction silicon carbide semiconductor device according to the embodiment is described. FIGS. 2, 3, 4, 5, 6, 7 and 8 are cross-sectional views schematically depicting states of the superjunction silicon carbide semiconductor device according to the embodiment during manufacture.

First, the n⁺-type silicon carbide substrate 1 containing an n-type single crystal 4H—SiC is prepared. Subsequently, at the first main surface of the n⁺-type silicon carbide substrate 1, the n-type buffer layer 17 and an n-type drift layer 2 are sequentially grown by epitaxy. As mentioned above, the n-type buffer layer 17 and the n-type drift layer 2 are assumed to have slightly different n-type dopant concentrations. The state up to here is depicted in FIG. 2.

Next, above the surface of the n-type drift layer 2, a SiO₂ mask 23 constituting a trench etching mask having predetermined openings is formed by a photolithography technique. The state up to here is depicted in FIG. 3.

Next, the SJ trenches 24 of a depth substantially equal to a thickness of the n-type drift layer 2 and not reaching the n⁺-type silicon carbide substrate 1 are formed in the n-type drift layer 2 by dry etching. The state up to here is depicted in FIG. 4.

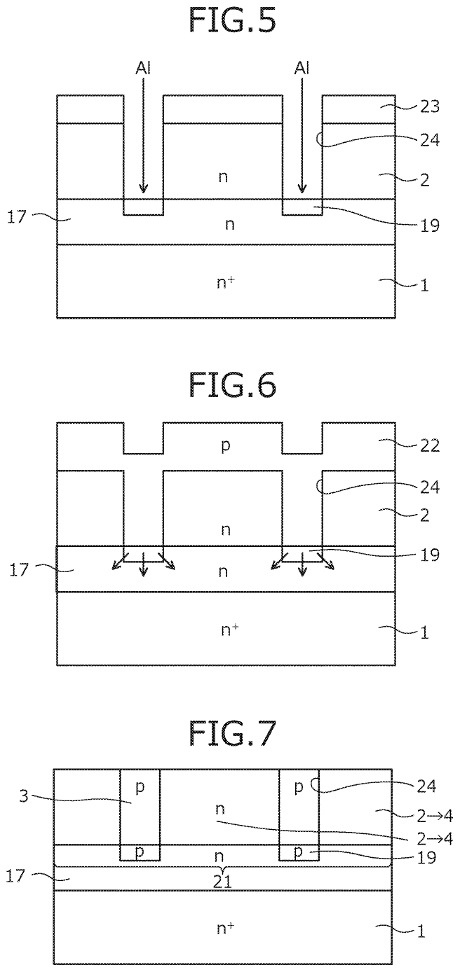

Next, a p-type dopant, etc. is ion-implanted at the bottoms of the SJ trenches 24, thereby forming the p-type regions 19. The ion implantation of the p-type dopant, etc. at the bottoms of the SJ trenches 24 introduces, in the n-type buffer layer 17, crystal defects caused by ion implantation. The state up to here is depicted in FIG. 5. Ion-implanted elements include, for example, Al, Al and an n-type dopant (phosphorus (P), nitrogen (N), etc.), Al and a rare gas element (neon (Ne), argon (Ar), krypton (Kr), xenon (Xe), etc.). In an instance of Al and an n-type dopant, or Al and a rare gas element, the concentration of the element to be implanted may be higher than that in an instance of Al alone and the amount of defects may be increased. As a p-type dopant, instead of Al, boron (B) may be used. In this instance, B alone, B and an n-type dopant, or B and a rare gas element may be ion-implanted. A temperature of the ion implantation, preferably, may be room temperature to prevent recovery of crystal defects formed by ion implantation during implantation.

A compensation concentration (concentration difference of p-type dopant and n-type dopant) of the p-type regions 19 is within a range of about a same dopant concentration (1×10¹⁶/cm³ to 1×10¹⁷/cm³) of the p-type epitaxial layer 22 formed below and preferably, a maximum concentration of a sum of ion-implanted elements may be 2×10¹⁷/cm³ or less. When the compensation concentration of the p-type regions 19 is higher than this, JFET resistance increases and when the compensation concentration is lower than this, the defects due to ion implantation decrease and thus, the effect of suppressing degradation due to conduction decreases.

Further, preferably, the thickness of each of the p-type regions 19 may be within a range of 0.1 μm to 1 μm. When the thickness of the p-type regions 19 is thinner than this, the p-type regions 19 disappear due to hydrogen etching during subsequent epitaxial growth of the p-type epitaxial layer 22 and when the thickness is thicker than this, high-acceleration ion implantation becomes necessary, whereby implantation costs increase.

Next, the SiO₂ mask 23 for forming the trenches is removed. Next, at the front surface of the n-type buffer layer 17, the p-type epitaxial layer 22 containing silicon carbide doped with a p-type dopant such as aluminum is formed by epitaxial growth, whereby the SJ trenches 24 are backfilled with the p-type epitaxial layer 22. The dopant concentration of the p-type epitaxial layer 22 is in a range of 1×10¹⁶ and 1×10¹⁷/cm³. The state up to here is depicted in FIG. 6.

The crystal defects due to ion implantation expand during the epitaxial growth and spread in the n-type buffer layer 17, whereby the lifetime of the drift layer decreases and degradation due to conduction when the body diodes conduct is suppressed.

Next, the surface of the p-type epitaxial layer 22 is ground, leaving portions of the p-type epitaxial layer 22 in the SJ trenches 24, whereby the parallel pn structure 21 configured by the p-type column regions 3 and the n-type column regions 4 is formed. The portions of the p-type epitaxial layer 22 in the SJ trenches 24 constitute the p-type column regions 3 and the regions of the n-type drift layer 2 between the p-type column regions 3 constitute the n-type column regions 4. In FIG. 7, “2→4” indicates the latter. The state up to here is depicted in FIG. 7.

Next, the first p⁺-type base regions 14 are formed by ion implantation and thereafter, at the front surface of the n-type drift layer 2, a lower n-type high-concentration region 5a containing silicon carbide is grown by epitaxy while nitrogen atoms are doped. Next, lower second p⁺-type base regions 15a are formed by selective ion implantation. Further, thereon, an upper n-type high-concentration region 5b containing silicon carbide is grown by epitaxy while nitrogen atoms are doped. Next, the upper second p⁺-type base regions 15b are formed by selective ion implantation. Portions of the lower n-type high-concentration region 5a and portions of the upper n-type high-concentration region 5b form the n-type high-concentration regions 5. Further, the lower second p⁺-type base regions 15a and the upper second p⁺-type base regions 15b form the second p⁺-type base regions 15.

Next, above the surfaces of the n-type high-concentration regions 5, the p-type base layer 6 doped with a p-type dopant such as aluminum is formed. Next, above the surface of the p-type base layer 6, an ion implantation mask having predetermined openings is formed by photolithography using, for example, an oxide film. An n-type dopant such as phosphorus (P) is ion-implanted in the openings, thereby forming the n⁺-type source regions 7 in portions of the p-type base layer 6, at the surface thereof. Next, the ion implantation mask used in forming the n⁺-type source regions 7 is removed and by a same method, an ion implantation mask having predetermined openings may be formed, a p-type dopant such as aluminum may be ion-implanted in portions of the p-type base layer 6, at the surface thereof, thereby forming the p⁺-type contact regions 8. The dopant concentration of the p⁺-type contact regions 8 is set to be higher than the dopant concentration of the p-type base layer 6.

Next, under an inert gas atmosphere of 1700 degrees C., a heat treatment (annealing) is performed, thereby implementing an activation process for the first p⁺-type base regions 14, the second p⁺-type base regions 15, the n⁺-type source regions 7, the p⁺-type contact regions 8, etc. As described, the ion-implanted regions may be collectively activated by a single session of the heat treatment or the heat treatment may be performed each time ion implantation is performed.

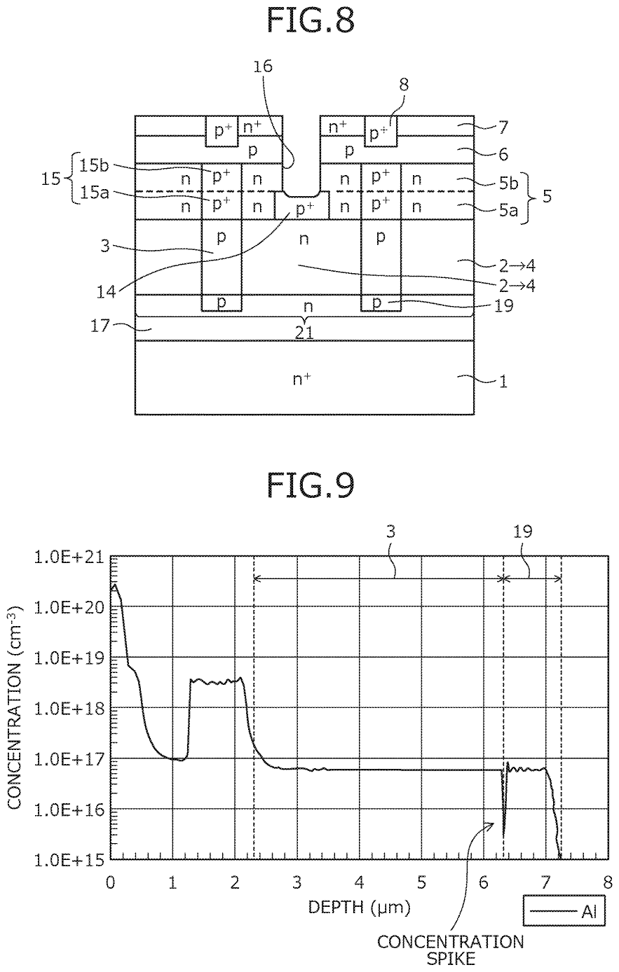

Next, above the surface of the p-type base layer 6, a mask for forming the trenches and having predetermined openings is formed by photolithography using, for example, an oxide film. Next, the trenches 16 that penetrate through the p-type base layer 6 and reach the n-type high-concentration regions 5 are formed by dry etching. The bottoms of the trenches 16 may reach the first p⁺-type base regions 14 formed in the n-type high-concentration regions 5. Next, the mask for forming the trenches is removed. The state up to here is depicted in FIG. 8.

Next, the gate insulating film 9 is formed along the surface of the n⁺-type source regions 7 and the bottoms and sidewalls of the trenches 16. The gate insulating film 9 may be formed by thermal oxidation at a temperature of about 1000 degrees C. under an oxygen atmosphere. Further, the gate insulating film 9 may be formed by a deposition method by a chemical reaction such as that for a high temperature oxide (HTO) or the like.

Next, on the gate insulating film 9, a poly-crystalline silicon layer doped with, for example, phosphorus atoms, is provided. The polycrystalline silicon layer may be formed so as to be embedded in the trenches 16. The polycrystalline silicon layer is patterned by photolithography, leaving portions thereof in the trenches 16, thereby forming the gate electrodes 10.

Next, for example, a phosphate glass is deposited so as to have a thickness of about 1 μm and cover the gate insulating film 9 and the gate electrodes 10, thereby forming the interlayer insulating film 11. Next, the barrier metal (not depicted) containing titanium (Ti) or titanium nitride (TiN) may be formed so as to cover the interlayer insulating film 11. The interlayer insulating film 11 and the gate insulating film 9 are patterned by photolithography, thereby forming contact holes exposing the n⁺-type source regions 7. In an instance in which the p⁺-type contact regions 8 are formed, contact holes exposing the n⁺-type source regions 7 and the p⁺-type contact regions 8 are formed.

Next, in the contact holes and on the interlayer insulating film 11, a conductive film (not depicted) is provided. The conductive film is selectively removed, leaving portions thereof in the contact holes, whereby the n⁺-type source regions 7 and the conductive film are in contact with each other. In an instance in which the p⁺-type contact regions 8 are formed, the n⁺-type source regions 7 and the p⁺-type contact regions 8 are in contact with the conductive film. The conductive film may be, for example, a nickel silicide. Next, the source electrode 12 containing aluminum, etc. is provided.

Next, on the second main surface of the n⁺-type silicon carbide semiconductor substrate 1, a back electrode containing nickel, etc. is provided. Thereafter, a heat treatment is performed under an inert gas atmosphere of a temperature of about 1000 degrees C., forming the drain electrode 18, which is in ohmic contact with the n⁺-type silicon carbide semiconductor substrate 1.

Next, for example, an electrode pad constituting the source electrode pad (not depicted) for soldering terminals is deposited on an upper portion of the interlayer insulating film 11 and on the source electrode 12 of the front surface of the silicon carbide semiconductor chip by a sputtering method. Thus, as described, the superjunction silicon carbide semiconductor device depicted in FIG. 1 is completed.

In FIG. 1, while a trench structure MOSFET is taken as an example, in an instance of a planar structure MOSFET in which the trenches 16 are not formed, the following changes suffice. In other words, in portions of the p-type base layer 6, at the surface thereof, n-type well regions are formed, the front surface side of the silicon carbide semiconductor chip is thermally oxidized, the gate insulating film 9 is formed, the p-type base layer 6 and regions formed at the surface of the p-type base layer 6 are covered by the gate insulating film 9, a polycrystalline silicon layer is formed on the gate insulating film 9 as the gate electrodes 10, the polycrystalline silicon layer is patterned and selectively removed, portions of the polycrystalline silicon layer on portions of the p-type base layer 6 between the n⁺-type source regions 7 and the n-type well regions are left, and the interlayer insulating film 11 is formed so as to cover the gate electrodes 7.

FIG. 9 is a graph depicting results of simulation (Monte Carlo method) of an Al concentration profile of p-type regions of the SJ-MOSFET according to the embodiment. In FIG. 9, a horizontal axis indicates depth from the surface of the p⁺-type contact regions 8 in units of μm. A vertical axis indicates the dopant concentration of Al in units of cm⁻³. As depicted in FIG. 9, at the boundaries between the p-type column regions 3 and the p-type regions 19, the dopant concentration of Al exhibits a concentration spike where the concentration suddenly decreases to about 2×10¹⁵/cm³. In other words, at the boundaries, the dopant concentration of Al has a region of not more than 1/10 of the maximum concentration of Al (in this example, about 8×10¹⁶/cm³) of the p-type regions 19. This is a structural characteristic associated with the manufacturing method of the SJ-MOSFET according to the embodiment and occurs because when ions are ion-implanted into the bottom of the trenches, the concentration at an outermost surface at the bottom of the trenches is low due to the influence of the ion implantation range. The dopant concentration of the p-type column regions 3 and that of the p-type regions 19 are about the same, in a range of 1×10¹⁶/cm³ to 1×10¹⁷/cm³.

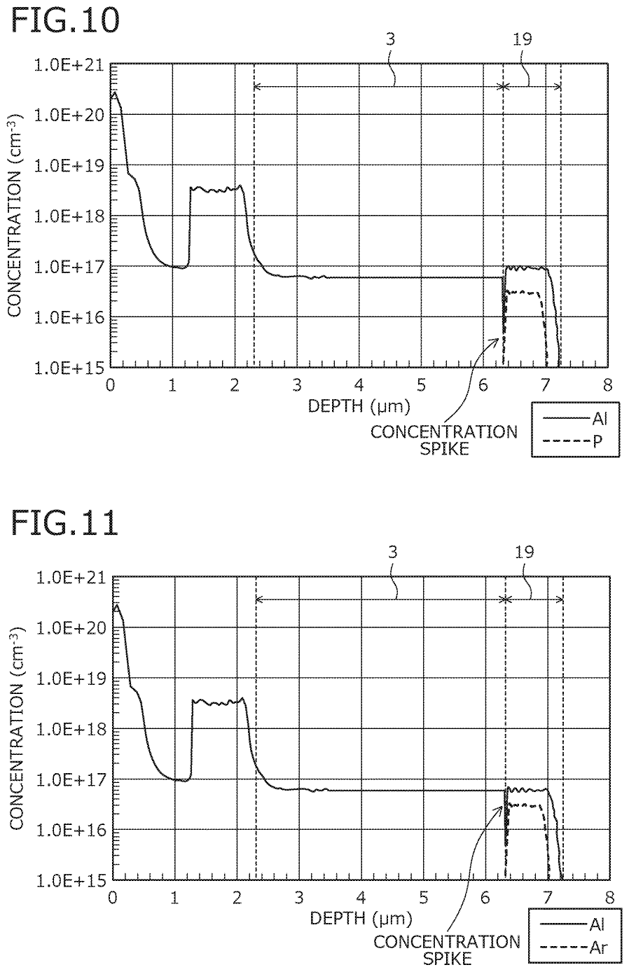

FIG. 10 is a graph depicting results of simulation of Al and P concentration profiles of p-type regions of the SJ-MOSFET according to the embodiment. In FIG. 10, a horizontal axis indicates depth from the surface of the p⁺-type contact regions 8 in units of μm. A vertical axis indicates the dopant concentrations of Al and P in units of cm⁻³. As depicted in FIG. 10, at the boundaries of the p-type column regions 3 and the p-type regions 19, the dopant concentration of Al exhibits a concentration spike where the concentration suddenly decreases to about 2×10¹⁵/cm³. In other words, similar to FIG. 9, in FIG. 10, at the boundaries of the p-type column regions 3 and the p-type regions 19, is a region of not more than 1/10 of the maximum concentration of Al (in this example about 1×10¹⁷/cm³) of the p-type regions 19. In at least a portion of the p-type regions 19 is a region where both Al and P are implanted.

Further, the compensation concentration of the p-type column regions 3 and the dopant concentration of the p-type regions 19 are about the same, in a range of 1×10¹⁶/cm³ to 1×10¹⁷/cm³. To prevent destruction of the crystal structure during ion implantation, preferably, the maximum concentration of the sum of an ion-implanted element may be 2×10¹⁷/cm³ or less. While FIG. 10 is an example of P, results are similar in an instance of N.

FIG. 11 is a graph depicting results of simulation of Al and Ar concentration profiles of p-type regions of the SJ-MOSFET according to the embodiment. In FIG. 11, a horizontal axis indicates depth from the surface of the p⁺-type contact regions 8 in units of μm. A vertical axis indicates the dopant concentrations of Al and Ar in units of cm⁻⁻. As depicted in FIG. 11, at the boundaries of the p-type column regions 3 and the p-type regions 19, the dopant concentration of Al exhibits a concentration spike where the concentration suddenly decreases to about 2×10¹⁵/cm³. In other words, similar to FIG. 9, in FIG. 11, at the boundaries of the p-type column regions 3 and the p-type regions 19, is a region of not more than 1/10 of the maximum concentration of Al (in this example, about 8×10¹⁶/cm³) of the p-type regions 19. In at least a portion of the p-type regions 19 is a region where both Al and Ar are implanted.

Further, the dopant concentration of the p-type column regions 3 and that of the p-type regions 19 are about the same, in a range of 1×10¹⁶/cm³ to 1×10¹⁷/cm³. To prevent destruction of the crystal structure during ion implantation, preferably, the maximum concentration of the sum of an ion-implanted element may be 2×10¹⁷/cm³ or less. While FIG. 11 is an example of Ar, results are similar in an instance of other inert elements (Ne, Kr, Xe).

As described above, according to the superjunction silicon carbide semiconductor device according to the embodiment and the method of manufacturing the superjunction silicon carbide semiconductor device, after the formation of the SJ trenches, ion-implantation of a p-type dopant, etc. is performed at the SJ trench bottoms, thereby introducing in the drift layer, defects due to the ion implantation. The crystal defects expand during epitaxial growth of the p-type epitaxial layer and spread in at least a portion of the drift layer, whereby the lifetime of the drift layer may be reduced. Thus, during body diode conduction, degradation due to the conduction may be suppressed. At the SJ trench bottoms, a structural characteristic due to the ion-implantation of a p-type dopant, etc. corresponds to the concentration spike at the boundaries of the p-type column regions 3 and the p-type regions 19, where the dopant concentration of Al is not more than 1/10 of the maximum concentration of Al of the p-type regions 19.

Furthermore, details of the suppression of degradation due to body diode conduction are described here. The crystal defects of the p-type regions 19 formed by ion implantation expand into the adjacent n-type buffer layer 17 and the n-type column regions 4, shortening the carrier lifetime of those regions. A main factor of degradation due to body diode conduction is that when holes, which are minority carriers, reach the n⁺-type silicon carbide substrate 1 and are of a certain density or greater, stacking faults (basal plane dislocations) remaining in the n⁺-type silicon carbide substrate 1 expand due to the energy of recombination with electrons. During conduction of the body diodes, even when a large amount of minority carriers (holes) are injected into the n-type column regions 4, if there is a region where the carrier lifetime of the n-type buffer layer 17 and the n-type column regions 4 is shortened, the minority carriers (holes) are suppressed from reaching the n⁺-type silicon carbide substrate 1. As a result, expansion of the stacking faults from the n⁺-type silicon carbide substrate 1 may be suppressed.

In the disclosure, while an example is described in which the main surface of the silicon carbide substrate containing silicon carbide is a (0001) plane and on the (0001) plane, MOS is configured, without limitation hereto, various modifications are possible such as with the wide band gap semiconductor, orientation of the substrate main surface, and the like. Further, in the embodiments of the disclosure, while a trench-type MOSFET is described as an example, without limitation hereto, application to semiconductor devices of various configurations such as MOS semiconductor devices like planar-type MOSFETs is possible. Further, in FIG. 1, a so-called semi-SJ structure in which the drift layer 64 is configured by the bulk drift layer 61 and the SJ structure 62 is depicted as an example. Instead of this, a full-SJ structure may be adopted in which the bulk drift layer 61 is omitted and the bottom surfaces of the p-type regions 19 are in contact with the n⁺-type silicon carbide substrate 1.

The superjunction silicon carbide semiconductor device according to the present disclosure and the method of manufacturing the superjunction silicon carbide semiconductor device achieve an effect in that degradation due to conduction when the body diodes conduct is suppressed and process costs may be reduced.

As described, the superjunction silicon carbide semiconductor device according to the present disclosure and the method of manufacturing the superjunction silicon carbide semiconductor device are useful for high-voltage semiconductor devices used in power converting equipment, power source devices such as those of various types of industrial machines, and the like.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. A superjunction silicon carbide semiconductor device, comprising:
a silicon carbide semiconductor substrate of a first conductivity type, having a front surface and a back surface;
a first semiconductor layer of the first conductivity type, provided at the front surface of the silicon carbide semiconductor substrate, the first semiconductor layer having a first surface and a second surface opposite to each other, the second surface facing the silicon carbide semiconductor substrate;
a parallel pn region in which a plurality of first column regions of the first conductivity type and a plurality of second column regions of a second conductivity type are disposed repeatedly alternating with each other in a plane parallel to the front surface of the silicon carbide semiconductor substrate, the parallel pn region being provided at the first surface of the first semiconductor layer, the parallel pn region having a first surface and a second surface opposite to each other, the second surface of the parallel pn region facing the silicon carbide semiconductor substrate;
a second semiconductor layer of the second conductivity type, provided at the first surface of the parallel pn region;
a plurality of first semiconductor regions of the first conductivity type, selectively provided in the second semiconductor layer and having a dopant concentration higher than that of the first semiconductor layer;
a plurality of gate electrodes, each provided via one of a plurality of gate insulating films in contact with a portion of the second semiconductor layer and a portion of the plurality of first semiconductor regions;
a first electrode in contact with the plurality of first semiconductor regions and the second semiconductor layer;
a second electrode provided at the back surface of the silicon carbide semiconductor substrate; and
a plurality of second semiconductor regions of the second conductivity type, doped with a dopant of the second conductivity type, provided in the first semiconductor layer, at bottom surfaces of the plurality of second column regions, and being in contact with the plurality of second column regions, respectively, wherein
at boundaries between the plurality of second semiconductor regions and the plurality of second column regions, a concentration of the dopant of the second conductivity type exhibits a concentration spike where the concentration decreases to 1/10 or less of a maximum concentration of the dopant of the second conductivity type of the plurality of second semiconductor regions.

2. The superjunction silicon carbide semiconductor device according to claim 1, wherein
each of the plurality of second semiconductor regions is a region implanted with the dopant of the second conductivity type only, or the dopant of the second conductivity type and a dopant of the first conductivity type, or the dopant of the second conductivity type and a rare gas element.

3. The superjunction silicon carbide semiconductor device according to claim 2, wherein
the dopant of the second conductivity type is aluminum or boron,
the dopant of the first conductivity type is phosphorus or nitrogen, and
the rare gas element is neon, argon, krypton, or xenon.

4. The superjunction silicon carbide semiconductor device according to claim 1, wherein
the plurality of second semiconductor regions has a compensation concentration in a range of 1×10¹⁶/cm³ to 1×10¹⁷/cm³, and
a maximum concentration of a sum of an implanted element is not more than 2×10¹⁷/cm³.

5. The superjunction silicon carbide semiconductor device according to claim 1, wherein
a thickness of each of the plurality of second semiconductor regions is in a range of 0.1 μm to 1 μm.

6. The superjunction silicon carbide semiconductor device according to claim 1, further comprising
a plurality of trenches penetrating through the plurality of first semiconductor regions and the second semiconductor layer and reaching the first semiconductor layer, and
the plurality of gate electrodes are provided via the plurality of gate insulating films in the plurality of trenches, respectively.

7. A method of manufacturing a superjunction silicon carbide semiconductor device, the method comprising:
preparing a silicon carbide semiconductor substrate of a first conductivity type, the silicon carbide semiconductor substrate having a front surface and a back surface;
forming a first semiconductor layer of the first conductivity type, at the front surface of the silicon carbide semiconductor substrate, the first semiconductor layer having a first surface and a second surface opposite to each other, the second surface facing the silicon carbide semiconductor substrate;
forming a plurality of superjunction (SJ) trenches from the first surface of the first semiconductor layer, the plurality of SJ trenches not reaching the silicon carbide semiconductor substrate;
ion-implanting bottoms of the plurality of SJ trenches, thereby forming a plurality of second semiconductor regions of a second conductivity type;
growing a third semiconductor layer of the second conductivity type by epitaxy so as to be embedded in the plurality of SJ trenches;
grinding a surface of the third semiconductor layer and leaving the third semiconductor layer in the plurality of SJ trenches, thereby forming at the first surface of the first semiconductor layer, a parallel pn region in which a plurality of first column regions of the first conductivity type and a plurality of second column regions of the second conductivity type repeatedly alternate each other in a plane parallel to the front surface, the parallel pn region having a first surface and a second surface opposite to each other, the second surface facing the silicon carbide semiconductor substrate;
forming a second semiconductor layer of the second conductivity type at the first surface of the parallel pn region;
selectively forming a plurality of first semiconductor regions of the first conductivity in the second semiconductor layer, the plurality of first semiconductor regions having a dopant concentration higher than that of the first semiconductor layer;
forming a plurality of gate electrodes, each via one of a plurality of gate insulating films in contact with a portion of the second semiconductor layer and a portion of the plurality of first semiconductor regions;
forming a first electrode in contact with the plurality of first semiconductor regions and the second semiconductor layer; and
forming a second electrode at the back surface of the silicon carbide semiconductor substrate.

8. The method of manufacturing the superjunction silicon carbide semiconductor device according to claim 7, wherein
the ion-implanting is performed using a dopant of the second conductivity type only, or a dopant of the second conductivity type and a dopant of the first conductivity type, or a dopant of the second conductivity type and a rare gas element.

9. The method of manufacturing the superjunction silicon carbide semiconductor device according to claim 7, wherein
the forming the plurality of gate electrodes includes forming a plurality of trenches penetrating through the plurality of first semiconductor regions and the second semiconductor layer and reaching the first semiconductor layer, the plurality of gate electrodes being formed in the plurality of trenches via the plurality of gate insulating films, respectively.
